(19) United States
(12) Patent Application Publication
(10) Pub. No.: US 2014/0167703 A1
(43) Pub. Date: Jun. 19, 2014

(54) Dynamic Line Termination of Communication Buses in Monitoring Circuits for Battery Modules and a Method for Performing the Line Termination during the Initialization of the Monitoring System

(71) Applicants: Samsung SDI Co., Ltd., Yongin-si (KR); Robert Bosch GmbH, Stuttgart (DE)

(72) Inventors: Chrysanthos Tzivanopoulos, Kornwestheim (DE); Thomas Schaedlich, Kornwestheim (DE)

(73) Assignees: Samsung SDI Co., Ltd., Yongin-si (KR); Robert Bosch GmbH, Stuttgart (DE)

(21) Appl. No.: 14/107,889

(22) Filed: Dec. 16, 2013

(30) Foreign Application Priority Data
Dec. 18, 2012 (DE) 10 2012 223 530.2

(51) Int. Cl. G01R 31/36

(52) U.S. Cl. CPC G01R 31/3606
USPC 320/136; 324/434

(57) ABSTRACT

A monitoring circuit for a battery module includes at least two terminals configured to be connected to bus lines of a bus system, a series circuit having a line terminating resistor, and a switching device. Ends of the series circuit are in each case electrically connected to one of the two terminals.

This application claims priority under 35 U.S.C. §119 to patent application no. DE 10 2012 223 530.2, filed on Dec. 18, 2012 in Germany, the disclosure of which is incorporated herein by reference in its entirety.

### BACKGROUND

The present disclosure relates to a monitoring circuit for a battery module which can be connected to a bus system and which has a controllable line termination resistor for terminating the bus lines of the bus system and a monitoring system having monitoring circuits according to the disclosure and a method for performing the line termination during the initialization of the monitoring system.

In a battery management system of the prior art for the management of the battery of an electric or hybrid vehicle, the individual cell voltages and/or the temperatures of battery modules or battery cells, respectively, must be measured and monitored on the basis of present safety concepts. According to the prior art, this is done separately for each battery cell, one monitoring circuit or cell sense circuit (CSC), respectively, being integrated for each battery module. Depending on the installation situation and granularity of the battery pack or of the battery, respectively, these monitoring circuits are constructed in a correspondingly modular or scalable fashion. Each of the monitoring circuits must be capable of communicating with a central battery control unit (BCU). The bus system needed for this purpose, or the communication bus, respectively, can be designed differently according to the prior art, in this arrangement. In automobile applications, for example, the CAN (controller area network) bus has become established.

The CAN bus is a multi-vendor digital bus system specified according to ISO11898. It is applied predominantly in a car for communication between different control devices. At the physical layer of the CAN bus, the digital information is transmitted via two bus lines having opposite voltage levels. When a logical one is transmitted, the driver circuit or the transceiver circuit, respectively, sets the two bus lines, which are designated as CAN HIGH and CAN LOW, with high impedance to an idle potential of VCC/2 or 2.5 V (recessive state, differential voltage equal to zero). During the transmission of the complementary information—a logical zero—the transceiver circuit increases the voltage of CAN HIGH (to approx. 3.5 V) and, at the same time, lowers the potential of CAN LOW (to approx. 1.5 V). This signal level (differential voltage >1 V) of the two bus lines is designated as the so-called dominant state.

The CAN bus and most of the bus systems of the prior art must be terminated at the ends of their bus lines by means of a line impedance or a line terminating resistor, respectively, in order to avoid so called reflections of the incoming signal at the ends of the bus system. With a wrongly terminated bus line, the signal would pass back through the line and become superimposed on other signals. According to the prior art, the line termination or the line terminating resistor, respectively, in each case within the monitoring circuits is permanently soldered into the ends of the bus lines of the bus system. In other embodiments of the prior art, the monitoring circuits provide a corresponding equipment option for line terminating resistors at the ends of the bus lines.

The latter has the disadvantage that it is no longer possible to treat all battery modules as so called common parts (variety of variants). As an alternative, the possibility exists of implementing the line termination by electronic or mechanical coding. Both of these alternatives also have the effect, however, that a battery module can no longer be treated as common part in the system integration since either the hardware or the software of battery modules designed in this manner differ from one anther. The ease of maintenance of such systems, too, is rather low.

Addressing of the monitoring circuits which are connected to a bus system of the prior art is provided by an addressing method as part of the controlled start-up of the modules. In this context, a monitoring circuit of the same position or the battery cell block to be monitored by it, respectively, is assigned the same unambiguous identification number. In this context, the addressing method is mostly controlled by the central controller which communicates with the control electronics of the monitoring circuits via a hardware line. To execute the addressing method, an activation signal is firstly conveyed from the central controller to the control electronics of the first monitoring circuit. The initialization and the issuing of the unambiguous identification number to the first monitoring circuit is then performed by these control electronics. After conclusion of the addressing of the first monitoring circuit, the activation signal is forwarded by the latter to the control electronics of a further monitoring circuit and the addressing of the latter is performed. The addressing method is concluded as soon as all monitoring circuits to be activated have received the activation signal and been assigned an unambiguous identification number.

### SUMMARY

According to the disclosure, a monitoring circuit for a battery module is provided which comprises two terminals for the connection to the bus lines of a bus system. Furthermore, the monitoring circuit comprises a transceiver circuit which is connected to the two terminals and is designed for responding to the reception of a logical signal with a corresponding change in the potentials at the terminals. Furthermore, the monitoring circuit has control electronics which are designed for communicating with external control units and the transceiver circuit, wherein the monitoring circuit can be connected to at least one battery cell of a battery module and is designed for measuring the temperature and/or the voltage of at least one battery cell connected to it.

According to the disclosure, the monitoring circuit has a series circuit of a line terminating resistor and a switching means, wherein the ends of the series circuit are in each case electrically connected to one of the two terminals.

By means of a monitoring circuit configured in this manner, it is possible to perform a termination of a bus system within the monitoring circuit optionally by adding the line terminating resistor. If a bus system or a monitoring system, respectively, is implemented with monitoring circuits according to the disclosure, a specially produced cable tree having line terminating resistors soldered in is no longer needed. As well, all monitoring circuits or battery modules, respectively, can then be produced as common parts both with respect to the hardware and the software components. This simplifies the maintainability and the commissioning of such monitoring systems greatly. Furthermore, the bus lines of the bus system are always terminated optimally at the active end of the bus lines during the start-up phase which results in improvement with respect to the radiation-induced interference on the bus system.

In a preferred embodiment, the switching means can be driven by the control electronics. As a result, the switching means is thus drivable by electronics which are located within the monitoring circuit and does not need to be driven by an external component.

The control electronics are designed preferably for causing the activation of the monitoring circuit and/or the closing of the switching means on reception of a control signal. The result is that the bus lines are terminated within the monitoring circuits precisely when this is required, for example during the addressing process.

Preferably, the series circuit is arranged within the transceiver circuit. The line terminating resistor can thus be produced as a component together with the transceiver circuit and can also be exchanged together with the latter in the case of damage as a result of which costs can be saved.

In a preferred embodiment, the switching means is constructed as MOSFET which operates in low-side mode. Since the MOSFET is connected to the bus line of the bus system having the low potential with its source terminal and to the other bus line having the higher potential with its drain terminal via a terminating resistor, the MOSFET operates in low-side mode. MOSFETs are cost-effective and very compact, that is to say can be implemented with a high density of integration. Furthermore, MOSFETs have a fast switching time and stable amplification and response times.

Furthermore, a monitoring system is provided which comprises a central controller which is connected to the two bus lines of a bus system and comprises at least two monitoring circuits according to the disclosure which are in each case connected via their two terminals to the two bus lines of the bus system. The monitoring system also has a hardware line via which the control electronics of the at least two monitoring circuits are connected to one another and to the central controller.

In a preferred development of this embodiment, the central controller is constructed as battery management system and comprises alternatively or additionally a transceiver circuit and alternatively or additionally a line terminating resistor via which the central controller is connected to the bus lines of the bus system. By this means, the bus system is also terminated by a line terminating resistor at the input end via the central controller.

Furthermore, a method for initializing a monitoring system is provided which comprises a monitoring system according to the disclosure. The method comprises the following method steps: activating a first one of the at least two monitoring circuits via an activation signal, conveyed via the hardware line, by the central controller, closing the switching means of the activated monitoring circuit by the control electronics of the activated monitoring circuit, building up communication between the control electronics of the activated monitoring circuit and the central controller. Issuing an unambiguous identification number to the activated monitoring circuit by the central controller, opening the switching means of the activated monitoring circuit by the control electronics of the activated monitoring circuit, conveying an activating signal via the hardware line from the control electronics of the activated monitoring circuit to the control electronics of a further deactivated monitoring circuit, restarting the method with the step of closing the switching means of the further monitoring circuit. Such a method enables optimized addressing of the monitoring circuits of a monitoring system to be performed. Since with each issue of an unambiguous identification number to in each case one of the monitoring circuits, an isochronous termination of the bus lines of the bus system within the respective monitoring circuit can be performed, the noise immunity of the bus system is improved during the addressing method.

In a preferred development of the above method for initializing a monitoring system, the method also comprises the step of ending the method as soon as all monitoring circuits of the monitoring system are activated. This defines an appropriate end condition for the method.

In a preferred development of this or the preceding method for initializing a monitoring system, the method is controlled by the central controller.

Furthermore, a battery with a monitoring system according to the disclosure is provided, the battery being constructed particularly preferably as a lithium ion battery. Advantages of such batteries are given by, among other things, their comparatively high energy density and their large thermal stability. A further advantage of lithium ion batteries is that they are not subject to any memory effect.

Furthermore, a motor vehicle having a battery having a monitoring system according to the disclosure is provided, the battery being connected to a propulsion system of the motor vehicle.

Advantageous developments of the disclosure are specified in the subclaims and described in the description.

### BRIEF DESCRIPTION OF THE DRAWINGS

Exemplary embodiments of the disclosure will be explained in greater detail with reference to the subsequent description and the drawings, in which:

FIG. 1 shows an exemplary embodiment of a monitoring circuit according to the disclosure for a battery module,

FIG. 2 shows an exemplary embodiment of the series circuit of a monitoring circuit according to the disclosure, and

FIG. 3 shows an exemplary embodiment of a monitoring system according to the disclosure.

### DETAILED DESCRIPTION

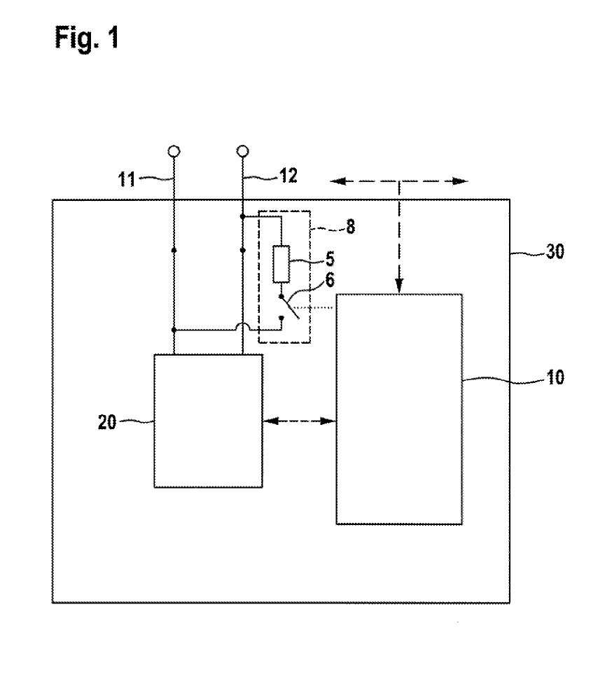

FIG. 1 shows a exemplary embodiment of a monitoring circuit 30 according to the disclosure for a battery module. The monitoring circuit 30 has two terminals 11, 12 via which it can be connected to the bus lines of a bus system. Such a bus system can be constructed purely illustratively as a CAN bus. Terminal 11 can then be connected purely illustratively to the first bus line of the CAN bus system which is designated here as CAN high and terminal 12 can be connected purely illustratively to the second bus line of the CAN bus system which is designated here as CAN low. Furthermore, the monitoring circuit 30 has a transceiver circuit 20 which is connected to a first and a second of terminals 11, 12 and is designed for responding to the reception of a logical signal having a corresponding change of the potentials at terminals 11, 12. If the monitoring circuit 30 is thus connected to the two bus lines, for example to those of a CAN bus system, the transceiver circuit 20 is also connected to these bus lines. The transceiver circuit 20 is designed for responding to a signal received via the bus lines or the terminals 11, 12 connected to these, respectively, with a change of the potential at one or at both of terminals 11, 12 in dependence on the respective received signal. Thus, the manner in which the transceiver circuit 20 changes the potential at terminals 11, 12 is dependent on the type of the received signal. In this context, the transceiver circuit 20 is capable both of a rectified, for example equal increase or reduction of the potential at both terminals 11, 12 and of a different change of the potential at terminals 11, 12. The transceiver circuit 20 is thus capable, for example, on the basis of an initial potential of the two terminals 11, 12, on reception of a signal of a particular type, of increasing the potential of one terminal 11 whilst it reduces the potential of the other terminal 12. Purely illustratively, the transceiver circuit 20 can place the two terminals 11, 12 to an idle potential of the supply voltage, for example on reception of a logical 1 whilst it increases the potential at a terminal 12 on reception of a logical 0 and reduces it at the other terminal 11. The manner in which the transceiver circuit 20 responds to the reception of a logical signal is selected purely illustratively in this exemplary embodiment and can deviate from the manner represented in this exemplary embodiment.

Furthermore, the monitoring circuit 30 has control electronics 10 which are designed for communicating with external control units and the transceiver circuit 20. Expressed in other words, the control electronics 10 are designed both for sending signals to external control units, for example to an external central controller such as, purely illustratively, a battery management system, and receiving signals from these. Furthermore, the control electronics 10 are designed for conveying signals to the control electronics 10 of other monitoring circuits 30 or receiving signals from these, respectively.

In this exemplary embodiment, the monitoring circuit 30 is connected to a battery module, not shown, which, purely illustratively, has six battery cells. Furthermore, the monitoring circuit 30 in this exemplary embodiment is connected to all six battery cells or to the electrodes of these six battery cells of the battery module, respectively (not shown). Furthermore the monitoring circuit 30 in this exemplary embodiment is designed for measuring the temperatures and the individual voltages of the six battery cells. Furthermore, the monitoring circuit 30 in this exemplary embodiment can convey the voltage and temperature data measured or determined, respectively, to an external central controller (not shown). Both the number of battery cells and the connection to the battery module is optional for a monitoring circuit 30 according to the disclosure and selected purely illustratively in the present exemplary embodiment. Monitoring circuits 30 according to the disclosure can also be implemented in which a monitoring circuit 30 is connected only to one or also to n battery cells and not to the battery module in which the battery cells are installed. Furthermore, the monitoring circuit 30 can also be designed for detecting other parameters of a battery cell apart from their individual voltage and temperature.

The monitoring circuit 30 has a series circuit 8 of a line terminating resistor 5 and a switching means 6, the ends of the series circuit 8 being connected electrically in each case to one of the two terminals 11, 12. Expressed in other words, the series circuit 8 of the switching means 6 and the line terminating resistor 5 is connected between terminals 11, 12. Terminals 11, 12 can thus be connected to one another via the line terminating resistor 5 via the switching means 6. If terminals 11, 12 are in each case connected to a bus system via a bus line, the latter can thus be terminated within the monitoring circuit 30 by closing the switching means 6. If the switching means 6 is closed, the two terminals 11, 12, and thus the bus lines, are connected electrically via the line terminating resistor 5.

In the present exemplary embodiment, the switching means 6 can be driven via the control electronics 10. Furthermore, the control electronics 10 are designed for initiating the activation of the monitoring circuit 30 and, in association therewith, the closing of the switching means 6, on reception of a control signal of a particular type, for example an activation signal. Just like the drivability of the switching means 6 by the control electronics 10, however, this is optional for the monitoring circuit 30 according to the disclosure. The control electronics 10 can also be designed for initiating the activation of the monitoring circuit 30 and the closing of the switching means 6 separately from one another.

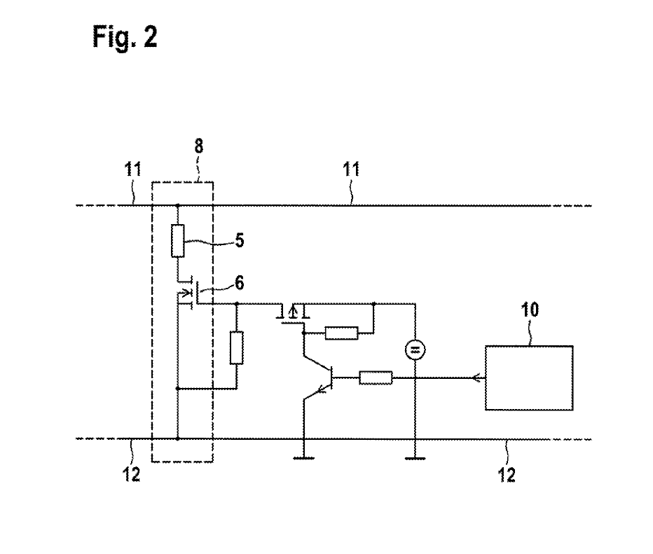

FIG. 2 shows an exemplary embodiment of the series circuit 8 of a monitoring circuit 30 according to the disclosure, of FIG. 1. In the latter, the ends of the series circuit 8 are connected in each case to a terminal 11, 12 of the monitoring circuit 30. In this exemplary embodiment, the switching means 6 is constructed as MOSFET, more precisely as n-channel MOSFET 6, the gate terminal of which is connected to the drain terminal of a further switching means constructed as MOSFET, more precisely to a switching means constructed as p-channel MOSFET, and to a terminal of a gate resistor. The other terminal of the gate resistor is connected to the source terminal of the switching means 6 and the series circuit 8. The gate terminal of the further switching means designed as p-channel MOSFET is connected to the collector of a switching means designed as bipolar transistor, the emitter of which is connected to ground and the base of which is connected purely illustratively to the control electronics 10 of the monitoring circuit 30 in the present exemplary embodiment. This embodiment of the series circuit 8 of a monitoring circuit 30 according to the disclosure is selected purely illustratively and can be designed in an arbitrarily different manner. Even when a MOSFET is used for the switching means 6, the embodiment of its drive circuit within a monitoring circuit 30 according to the disclosure can be arbitrary in accordance with the prior art.

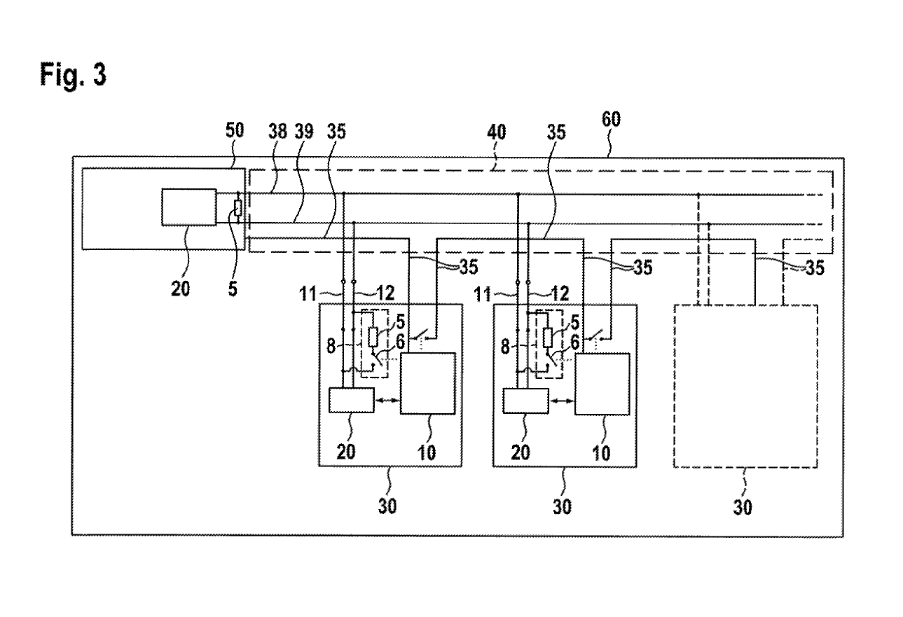

FIG. 3 shows an exemplary embodiment of a monitoring system 60 according to the disclosure. This monitoring system 60 has three monitoring circuits 30 according to the disclosure, two of which are shown designed whilst the third monitoring circuit 30 is only indicated. The monitoring circuits 30 according to the disclosure are here designed as represented in the description relating to FIG. 1. The identically designated components correspond to those of the first exemplary embodiment of FIG. 1 so that what has been said earlier can also be applied to the exemplary embodiment of FIG. 3. The monitoring system 60 has a bus system 40, two bus lines 38, 39 of which are shown. These bus lines 38, 39 are in each case connected electrically conductively to terminals 11, 12 of the monitoring circuits 30 according to the disclosure. Furthermore, the bus lines 38, 39 in this exemplary embodiment are connected at the input to a central controller 50 which has a line terminating resistor 5, optional for a monitoring system 60 according to the disclosure and permanently connected to the bus lines 38, 39, and an optional transceiver circuit 20 also connected to bus lines 38, 39. In this context, the central controller 50, like the monitoring circuits 30 according to the disclosure with the switching means 6 closed, is connected to the bus lines 38, 39 via the line terminating resistor 5 and the transceiver circuit 20. The terminals of the line terminating resistor 5 of the central controller 50 are thus connected to in each case one of the two bus lines 38, 39 which are connected at their input end to the transceiver circuit 20 of the central controller 50.

Furthermore, the monitoring system 60 has a hardware line 35 via which the control electronics 10 of the three monitoring circuits 30 are connected to one another and to the central controller 50. In the exemplary embodiment of FIG. 3, the control electronics 10 of all monitoring circuits 30 can cause the interruption of the hardware line 35 via in each case an optional switching means. If the switching means, optional for a monitoring system 60 according to the disclosure, are closed, an activation signal, for example, which is present at the control electronics 10 of a monitoring circuit 30 via the hardware line 35 can be conveyed by this control electronics 10 to the control electronics 10 of a further monitoring circuit 30.

For an initialization of the monitoring system 60 according to the disclosure which, in the present exemplary embodiment, is controlled purely illustratively by the central controller 50, the latter initially generates an activation signal and conveys the latter via the hardware line 35 to the control electronics 10 of a first one of the three monitoring circuits 30, as a result of which the latter is activated. At the same time as the monitoring circuit 30 is activated, its control electronics 10 causes the switching means 6 to close so that the bus lines 38, 39 are terminated within the activated monitoring circuit 30 via terminals 11, 12. Following this, a communication between the control electronics 10 of the activated monitoring circuit 30 and the central controller 50 is built up via the hardware line 35. If the communication between the central controller 50 and the monitoring circuit 30 has been built up, the central controller 50 assigns an unambiguous identification number to the activated monitoring circuit 30. Thus, an unambiguous identification number is issued to the activated monitoring circuit 30. If this issue has taken place, the control electronics 10 of the activated monitoring circuit 30 causes the switching means 6 to open, closes the optional switching means located in the hardware line 35 and conveys on this path the activation signal via the hardware line 35 to the control electronics 10 of the adjacent, further deactivated monitoring circuit 30. By this means, this further monitoring circuit 30 is activated and the process already performed with a first one of the monitoring circuits 30 again begins, now with this further monitoring circuit 30, with the step of closing the switching means 6 of this further monitoring circuit 30. With this further one and with the third one of the monitoring circuits 30 of the monitoring system 60, an initialization is then performed as described above for the first one of the monitoring circuits 30. In this exemplary embodiment, the central controller 50 only aborts the initialization when all monitoring circuits 30 of the monitoring system 60 have been activated and have been assigned an unambiguous identification number. The order for opening and closing the switching means 6 and the switching means for forwarding the hardware line 35 can vary.

A monitoring system 60 according to the disclosure can also comprise only two or also more than three, for example four or n monitoring circuits 30 according to the disclosure.

What is claimed is:

1. A monitoring circuit for a battery module comprising:
at least two terminals configured to be connected to bus lines of a bus system;
a transceiver circuit connected to the at least two terminals and configured to respond to a reception of a logical signal with a corresponding change in potential at the at least two terminals;
control electronics configured to communicate with external control units and the transceiver circuit;
a series circuit including a line terminating resistor and a switching device, wherein ends of the series circuit are in each case electrically connected to a terminal of the at least two terminals,
wherein the monitoring circuit is configured to be connected to at least one battery cell of a battery module and is further configured to measure a temperature and/or a voltage of at least one battery cell that is connected to the monitoring circuit.

2. The monitoring circuit according to claim 1, wherein the switching device is configured to be driven by the control electronics.

3. The monitoring circuit according to claim 1, wherein the control electronics are configured to cause an activation of a further monitoring circuit and/or a closing of the switching device on reception of a control signal.

4. The monitoring circuit according to claim 1, wherein the series circuit is arranged within the transceiver circuit.

5. The monitoring circuit according to claim 1, wherein the switching device is configured to operate in high-side mode.

6. The monitoring circuit according to claim 1, wherein the switching device is configured to operate in low-side mode.

7. A monitoring system comprising:
a central controller connected to at least two bus lines of a bus system;
at least one monitoring circuit including (i) at least two terminals configured to be connected to the at least two bus lines of the bus system, (ii) a transceiver circuit connected to the at least two terminals and configured to respond to a reception of a logical signal with a corresponding change in potential at the two terminals, (iii) control electronics configured to communicate with external control units and the transceiver circuit, and (iv) a series circuit including a first line terminating resistor and a switching device; and
a hardware line via which the control electronics of the monitoring circuit are connected to the central controller,
wherein ends of the series circuit are in each case electrically connected to a terminal of the at least two terminals, and
wherein the monitoring circuit is configured to be connected to at least one battery cell of a battery module and is further configured to measure a temperature and/or a voltage of at least one battery cell that is connected to the monitoring circuit.

8. The monitoring system according to claim 7, wherein the central controller includes a battery management system, a transceiver circuit, and/or a second line terminating resistor via which the central controller is connected to the at least two bus lines of the bus system.

9. The monitoring system according to claim 7, further comprising:
a battery.

10. The monitoring system according to claim 9, wherein the battery is connected to a propulsion system of a motor vehicle.

11. A method for initializing a monitoring system including a central controller connected to at least two bus lines of a bus system, at least two monitoring circuits each including (i) at least two terminals configured to be connected to the at least two bus lines of the bus system, (ii) a transceiver circuit connected to the at least two terminals and configured to respond to a reception of a logical signal with a corresponding change in potential at the two terminals, (iii) control electronics configured to communicate with external control units and the transceiver circuit, and (iv) a series circuit including a line terminating resistor and a switching device, and a hardware line via which the control electronics of the monitoring circuit are connected to the central controller, the method comprising:
activating a first monitoring circuit of the at least two monitoring circuits via an activation signal conveyed via the hardware line by the central controller;
closing the switching device of the activated first monitoring circuit by the control electronics of the activated first monitoring circuit;
building up a communication between the control electronics of the activated first monitoring circuit and the central controller;
issuing an unambiguous identification number to the activated first monitoring circuit by the central controller;
opening the switching device of the activated first monitoring circuit by the control electronics of the activated first monitoring circuit;
conveying an activating signal via the hardware line from the control electronics of the first activated monitoring circuit to the control electronics of a further deactivated monitoring circuit of the at least two monitoring circuits; and
restarting the method with the step of closing the switching device of the further monitoring circuit,
wherein ends of the series circuit are in each case electrically connected to a terminal of the at least two terminals, and
wherein the at least two monitoring circuits are configured to be connected to at least one battery cell of a battery module and are further configured to measure a temperature and/or a voltage of at least one battery cell that is connected to the at least two monitoring circuits.

12. The method for initializing a monitoring system according to claim 11, further comprising:
ending the method as soon as all monitoring circuits of the monitoring system are activated.

13. The method for initializing a monitoring system according to claim 11, wherein the method is controlled by the central controller.
